(19) United States
(12) Patent Application Publication
(10) Pub. No.: US 2025/0385115 A1
(43) Pub. Date: Dec. 18, 2025

(54) SUBSTRATE TRANSPORT DEVICE, SUBSTRATE TRANSPORT SYSTEM, AND SUBSTRATE TRANSPORT METHOD

(71) Applicant: KABUSHIKI KAISHA YASKAWA DENKI, Fukuoka (JP)

(72) Inventors: Mina Orii, Fukuoka (JP); Dai Shimizu, Fukuoka (JP); Yoshiaki Kubota, Fukuoka (JP); Hiromitsu Akae, Fukuoka (JP)

(73) Assignee: KABUSHIKI KAISHA YASKAWA DENKI, Fukuoka (JP)

(21) Appl. No.: 19/230,239

(22) Filed: Jun. 6, 2025

(30) Foreign Application Priority Data
Jun. 12, 2024 (JP) 2024-095255

(51) Int. Cl. H01L 21/677; B65G 54/02

(52) U.S. Cl. CPC H01L 21/67709; B65G 54/02

(57) ABSTRACT

Object

To reduce an installation area and improve the efficiency of transporting a substrate.

Solution to Problem

A substrate transport device 28 includes a stator 11 including a plurality of coil units 17, a first mover 35 including first magnet units 41A and 41B and configured to float and move above the stator 11, a second mover 37 including second magnet units 43A and 43B and configured to float and move above the stator 11, a bearing 39 configured to guide the first mover 35 and the second mover 37 to be operable relative to each other, and a substrate support 21A connected to the first mover 35 and the second mover 37 and configured to support a substrate W.

### CROSS REFERENCE TO RELATED APPLICATIONS

This application claims the benefit of priority to Japanese Patent Application Number 2024-095255 filed on Jun. 12, 2024. The entire contents of the above-identified application are hereby incorporated by reference.

### TECHNICAL FIELD

The disclosed embodiments relate to a substrate transport device, a substrate transport system, and a substrate transport method.

### BACKGROUND ART

Patent Document 1 describes a semiconductor processing facility used to transfer a semiconductor substrate between processing chambers. The semiconductor processing facility includes a planar motor including an array of coils, and a substrate carrier including magnets and configured to float up by mutual action of magnetic fields generated by the coils and magnetic fields generated by the magnets. The substrate carrier has a substrate supporting surface on which a substrate is to be placed and transports the substrate between the processing chambers.

### CITATION LIST

### Patent Literature

Patent Document 1: JP 2018-504784 T

### SUMMARY OF INVENTION

### Technical Problem

In the semiconductor processing facility of the prior art, the substrate supporting surface is provided so as to protrude from the substrate carrier, and the substrate carrier moves the protruding substrate supporting surface into the processing chamber, thereby loading and unloading the substrate into and from the processing chamber. However, since the substrate carrier moves in a state in which the substrate supporting surface protrudes, the installation area of the planar motor increases, and the substrate carrier does not turn in a small space, so that there is a problem that the transport efficiency decreases.

The present disclosure has been made in view of the above problems, and an object of the present disclosure is to provide a substrate transport device, a substrate transport system, and a substrate transport method that can reduce an installation area and improve transport efficiency of a substrate.

### Solution to Problem

In order to solve the above problem, according to one aspect of the present disclosure, there is applied a substrate transport device including: a stator including a plurality of coils, a first mover including a first magnet and configured to float and move above the stator, a second mover including a second magnet and configured to float and move above the stator, a guide member configured to guide the first mover and the second mover to be operable relative to each other, and a substrate support connected to at least one of the first mover or the second mover and configured to support a substrate.

Furthermore, according to another aspect of the present disclosure, there is applied a substrate transport device including: a stator including a plurality of coils, a first mover including a first magnet and configured to float and move above the stator, a second mover including a second magnet and configured to float and move above the stator, an elastic body configured to couple the first mover and the second mover to be operable relative to each other, and a substrate support connected to at least one of the first mover or the second mover and configured to support a substrate.

Moreover, according to another aspect of the present disclosure, there is applied a substrate transport system including: a transport chamber including a stator and where a substrate is transported, the stator including a plurality of coils, a processing chamber disposed at a periphery of the transport chamber and where a predetermined process is executed on the substrate, an opening/closing door configured to open/close an opening of the processing chamber, a first mover including a first magnet and configured to float and move above the stator in the transport chamber, a second mover including a second magnet and configured to float and move above the stator in the transport chamber, a guide member configured to guide the first mover and the second mover to be operable relative to each other, and a substrate support connected to at least one of the first mover or the second mover and configured to support the substrate.

In addition, according to another aspect of the present disclosure, there is applied a substrate transport method for transporting a substrate, the method including: moving, in a transport chamber including a stator and where the substrate is transported, the stator including a plurality of coils, a first mover and a second mover above the stator in a state of remaining stationary relative to each other, the first mover including a first magnet and configured to float and move above the stator in the transport chamber, the second mover including a second magnet and configured to float and move above the stator in the transport chamber, operating the first mover and the second mover relative to each other at a position facing a processing chamber disposed at a periphery of the transport chamber and where a predetermined process is executed on the substrate, and causing a substrate support to enter the processing chamber by opening an opening/closing door configured to open/close an opening of the processing chamber and causing the first mover or the second mover to straddle the opened opening/closing door, the substrate support connected to at least one of the first mover or the second mover and configured to support the substrate.

### Advantageous Effects of Invention

According to the substrate transport device and the like of the present disclosure, the installation area can be reduced, and the transport efficiency of the substrate can be improved.

### BRIEF DESCRIPTION OF DRAWINGS

FIG. 1 is a top view illustrating an example of an overall configuration of a substrate transport system in a simplified manner.

FIG. 2 is a top view illustrating an example of the configurations of a mover and a substrate support in a simplified manner.

FIG. 3 is a cross-sectional view corresponding to an A-A cross section in FIG. 2.

FIG. 4 is a top view illustrating an example of a positional relationship among a sensor, a first target, and a second target when the mover is located in an area.

FIG. 5 is a cross-sectional view corresponding to a B-B cross section in FIG. 4.

FIG. 6 is a top view illustrating an example of the configurations of the mover and a stator in a case where a first mover and a second mover perform rotating operation.

FIG. 7 is a top view illustrating an example of a configuration of the mover.

FIG. 8 is a cross-sectional view corresponding to a C-C cross section in FIG. 7.

FIG. 9 is a top view illustrating an example of a configuration of the substrate support.

FIG. 10 is a top view illustrating an example of the configurations of the mover and the stator in a case where the first mover and the second mover perform linear operation.

FIG. 11 is a top view illustrating an example of the configurations of the mover and the substrate support.

FIG. 12 is a top view illustrating an example of the configurations of the mover and the stator in a case where the second mover is disposed so as to surround a periphery of the first mover.

FIG. 13 is a top view illustrating an example of a configuration of the mover in a case where the first mover and the second mover are coupled by an elastic body.

FIG. 14 is a top view illustrating an example of an overall configuration of the substrate transport system, illustrating a utilization example of a mover in which the first mover and the second mover are coupled by the elastic body in a simplified manner.

FIG. 15 is a diagram illustrating an example of an operation of fine adjustment using the elastic body.

FIG. 16 is a diagram illustrating an example of the operation of fine adjustment using the elastic body.

FIG. 17 is a diagram illustrating an example of the operation of fine adjustment using the elastic body.

FIG. 18 is a diagram conceptually illustrating an example of an operation in which the mover straddles the opening/closing door in a case where the mover is configured to straddle the opening/closing door.

FIG. 19 is a diagram conceptually illustrating an example of the operation in which the mover straddles the opening/closing door.

FIG. 20 is a diagram conceptually illustrating an example of the operation in which the mover straddles the opening/closing door.

FIG. 21 is a diagram conceptually illustrating an example of the operation in which the mover straddles the opening/closing door.

FIG. 22 is a diagram conceptually illustrating an example of the operation in which the mover straddles the opening/closing door.

FIG. 23 is a diagram illustrating an example of a configuration of the substrate support in a case where the mover is configured to straddle the opening/closing door.

FIG. 24 is a diagram illustrating an example of a configuration of the substrate support in the case where the mover is configured to straddle the opening/closing door.

FIG. 25 is a top view illustrating an example of a configuration of a mover with a simplified configuration.

FIG. 26 is a top view illustrating an example of a configuration of a mover with a simplified configuration.

### DESCRIPTION OF EMBODIMENTS

Embodiments will be described below with reference to the drawings.

### 1. CONFIGURATION OF SUBSTRATE TRANSPORT SYSTEM

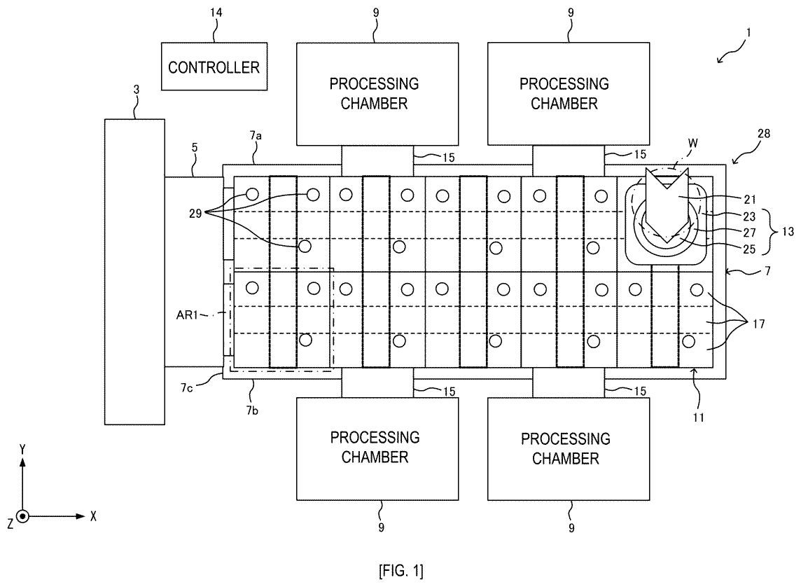

An outline of a configuration of a substrate transport system 1 according to an embodiment will be described with reference to FIGS. 1 to 5. The substrate transport system 1 is a system configured to transport a substrate W to be processed under a vacuum environment and execute a predetermined process on the substrate W. The substrate Wis, for example, a semiconductor wafer or the like.

FIG. 1 illustrates an example of an overall configuration of a substrate transport system 1 in a simplified manner. As illustrated in FIG. 1, the substrate transport system 1 includes an atmospheric transport chamber 3, a load lock chamber 5, a vacuum transport chamber 7, a plurality of processing chambers 9, a stator 11, a mover 13, and a controller 14.

The atmospheric transport chamber 3 is in an atmospheric atmosphere, and is provided with an atmospheric transport device (not illustrated) configured to transport the substrate W. The atmospheric transport device takes out the substrate W accommodated in a load port (not illustrated) and places the substrate W in the load lock chamber 5. Furthermore, the atmospheric transport device takes out the substrate W placed in the load lock chamber 5 and accommodates the substrate W in the load port.

The load lock chamber 5 has a placement table (not illustrated) on which the substrate W is placed, and controls the pressure between the atmospheric pressure and the vacuum when the substrate W is transported between the atmospheric transport chamber 3 and the vacuum transport chamber 7.

The interior of the vacuum transport chamber 7 (an example of a transport chamber) is depressurized to a vacuum atmosphere, and the substrate W is transported in the vacuum atmosphere. In the example illustrated in FIG. 1, the vacuum transport chamber 7 is formed in a substantially rectangular shape when viewed from above. A plurality of (e.g., two each, total of four) processing chambers 9 are connected to each of the opposing wall portions 7a and 7b on the long sides of the vacuum transport chamber 7 via an opening/closing door 15. The load lock chamber 5 is connected to one wall portion 7c on a short side of the vacuum transport chamber 7 via an opening/closing door (not illustrated). In the present embodiment, the longitudinal direction of the vacuum transport chamber 7 (stator 11), that is, the direction in which the plurality of processing chambers 9 having the opening/closing doors 15 in the same direction are arranged side by side is defined as an X-axis direction. Furthermore, a short direction of the vacuum transport chamber 7 (stator 11), that is, a direction in which the two processing chambers 9 having the opening/closing doors 15 in opposite directions face each other is defined as a Y-axis direction. Moreover, an up-down direction is defined as a Z-axis direction. Note that the vacuum transport chamber 7 may have a shape other than a rectangular shape.

In the vacuum transport chamber 7, the stator 11 including a plurality of coil units 17 arrayed in a lattice shape and the mover 13 including magnet units 19 and 20 (see FIGS. 3 and 5) are disposed. The coil unit 17 is configured as a coil unit by integrating a plurality of coils. Each of the magnet units 19 and 20 is configured as a magnet unit by integrating a plurality of permanent magnets. The stator 11 and the mover 13 constitute a planar motor. The mover 13 floats by mutual action between a magnetic field generated by the coil unit 17 and a magnetic field generated by the magnet units 19 and 20, and its position is controlled by the controller 14. A substrate support 21 configured to support the substrate W is connected to the mover 13. The mover 13 transports the substrate W between the load lock chamber 5 and the processing chamber 9 and between the plurality of processing chambers 9. Note that although only one mover 13 is illustrated in FIG. 1, a plurality of movers 13 may be disposed.

The processing chamber 9 is disposed at a periphery of the vacuum transport chamber 7, and executes a predetermined process on the substrate W. In the example illustrated in FIG. 1, for example, four processing chambers 9 are connected to the wall portions 7a and 7b, two processing chambers for each wall portion, via the opening/closing doors 15. In each processing chamber 9, a predetermined process such as a film forming process, an etching process, an ashing process, or a cleaning process is executed on the substrate W. Note that the number of processing chambers 9 is not particularly limited, and may be singular or plural other than four according to the number of processes to be executed. The opening/closing door 15 opens and closes the opening of the processing chamber 9. The opening/closing door 15 is also referred to as a gate valve. In each processing chamber 9, the substrate W is delivered to and from the substrate support 21 of the mover 13 in a state where the opening/closing door 15 is opened.

The controller 14 controls the operation of each component of the substrate transport system 1. For example, the controller 14 controls the processing of the substrate W in each processing chamber 9, the position of the mover 13 and the operation of the substrate support 21 in the vacuum transport chamber 7, the opening/closing of the opening/closing door 15, and the like. The controller 14 is configured as, for example, a computer. Although not illustrated, the controller 14 may include, for example, a processor such as a CPU, a memory such as a ROM or a RAM, an input device, an output device, a recording device, a communication device, and the like.

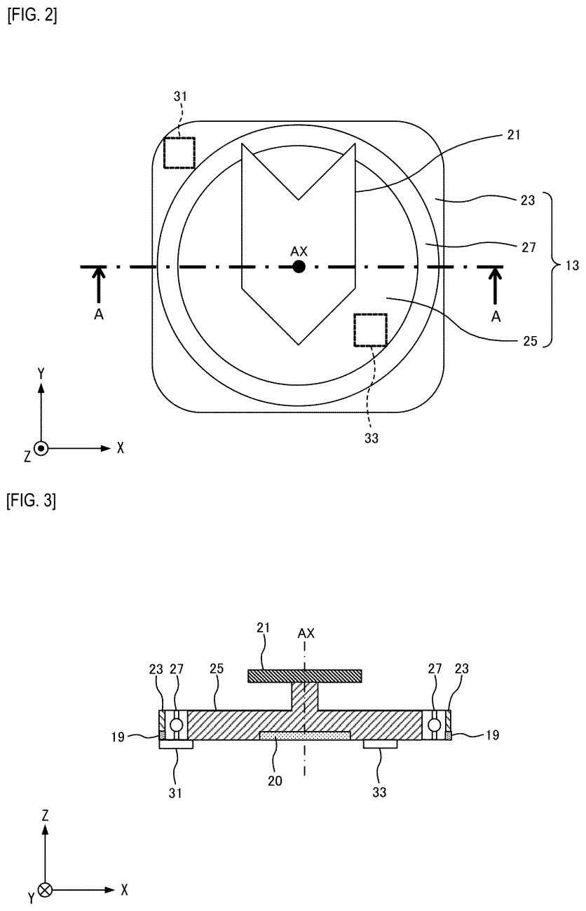

FIGS. 2 and 3 illustrate an example of the configurations of the mover 13 and the substrate support 21 in a simplified manner. FIG. 3 is a cross-sectional view corresponding to an A-A cross section in FIG. 2. As shown in FIGS. 2 and 3, the mover 13 includes a first mover 23, a second mover 25, and a bearing 27. The first mover 23 (an example of a first mover) includes a first magnet unit 19 (an example of a first magnet) on the lower side, and moves while floating above the stator 11. The second mover 25 (an example of a second mover) includes a second magnet unit 20 (an example of a second magnet) on the lower side, and moves while floating above the stator 11. The bearing 27 (an example of a guide member) guides the first mover 23 and the second mover 25 so as to be relatively operable to each other. The stator 11, the first mover 23, the second mover 25, the bearing 27, and the substrate support 21 constitute a substrate transport device 28.

In the example illustrated in FIGS. 1 to 5, the second mover 25 has a substantially circular shape, and the first mover 23 has a substantially quadrangular shape. The first mover 23 is disposed so as to surround the periphery of the second mover 25. The bearing 27 regulates the relative operating direction of the first mover 23 and the second mover 25 to the rotating direction about the rotation axis AX parallel to the Z-axis direction. At least one of the first mover 23 or the second mover 25 moves along a direction regulated by the bearing 27. That is, at least one of the first mover 23 or the second mover 25 rotates in the rotating direction about the rotation axis AX.

In the stator 11, the controller 14 controls the current independently for the coil unit 17 in a region (an example of a first region) facing the first mover 23 in the Z-axis direction and the coil unit 17 in a region (an example of a second region) facing the second mover 25 in the Z-axis direction, among the plurality of coil units 17. Accordingly, the controller 14 can control the operation of the first mover 23 and the operation of the second mover 25 independently of each other. For example, when the mover 13 moves between the processing chambers 9, the first mover 23 and the second mover 25 move above the stator 11 in a state of remaining stationary relative to each other. Note that the movement of the mover 13 includes a movement in the horizontal direction (each direction on the XY plane including the X-axis direction and the Y-axis direction) and a movement in the rotating direction about the rotation axis AX. That is, control with three degrees of freedom is possible. Furthermore, the movement may include an up-down movement in the Z-axis direction. In this case, for example, the mover 13 can be inclined in the rotating direction (ey direction) about the Y-axis by moving one side and the other side of the mover 13 in the X-axis direction in opposite directions in the Z-axis direction. Furthermore, for example, the mover 13 can be inclined in the rotating direction (ex direction) about the X-axis by moving one side and the other side of the mover 13 in the Y-axis direction in opposite directions in the Z-axis direction. In this case, control with six degrees of freedom is possible.

Furthermore, when the mover 13 is located in the vicinity of the opening/closing door 15 of the processing chamber 9, at least one of the first mover 23 or the second mover 25 relatively rotates about the rotation axis AX. The substrate support 21 is configured such that the position at which the substrate W is supported with respect to the first mover 23 or the second mover 25 is adjusted based on at least one of the rotating direction of each of the first mover 23 and the second mover 25 or the rotation speed of each of the first mover 23 and the second mover 25. For example, the substrate support 21 may include an arm that includes at least one of a plurality of link members or a plurality of transmission members and is configured to be extendable/contractible based on the relative operation of the first mover 23 and the second mover 25. Note that in FIGS. 1 to 5, the substrate support 21 is illustrated in a simplified manner.

As illustrated in FIG. 1, the stator 11 has a plurality of sensors 29 configured to detect the positions of the first mover 23 and the second mover 25. Furthermore, as illustrated in FIGS. 2 and 3, the first mover 23 includes a first target 31 (an example of a first target) to be detected by each of the plurality of sensors 29. The second mover 25 includes a second target 33 (an example of a second target) to be detected by each of the plurality of sensors 29. In FIGS. 2 and 3, one first target 31 and one second target 33 are provided, but two or more of each target may be provided. In addition, in FIGS. 2 and 3, the first target 31 and the second target 33 are respectively formed in a quadrangular shape, but may be formed in other shapes such as, for example, a ring shape along the outer periphery of the first mover 23 and the second mover 25. A detection signal of each sensor 29 is transmitted to the controller 14. The plurality of sensors 29 are arranged in a pattern having a predetermined regularity so as to be able to detect the positions of the first mover 23 and the second mover 25 even when the mover 13 is located at any position on the stator 11. In the example illustrated in FIG. 1, the sensor 29 is arranged at three locations for each area AR1 on the stator 11 corresponding to the size of the mover 13.

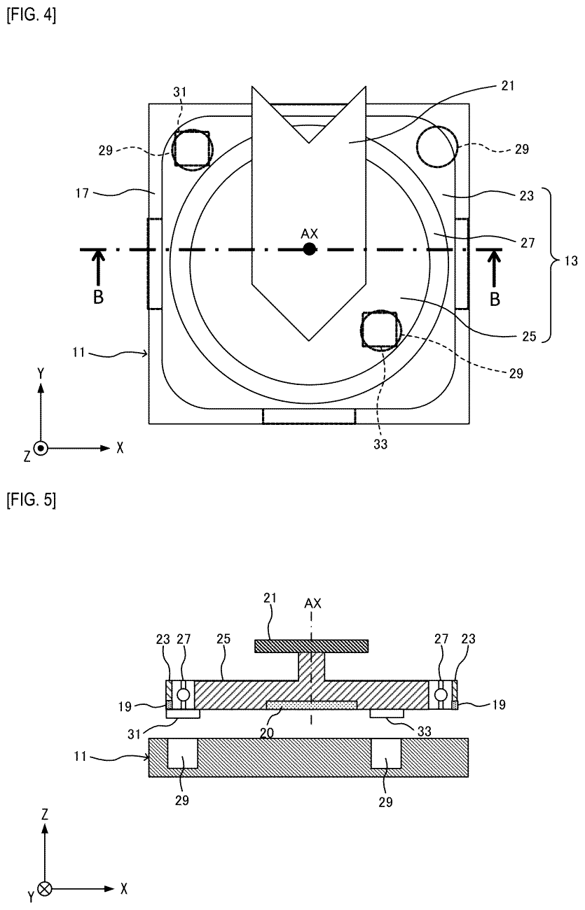

FIGS. 4 and 5 illustrate an example of the positional relationship among the sensor 29, the first target 31, and the second target 33 when the mover 13 is located in the area AR1. FIG. 5 is a cross-sectional view corresponding to a B-B cross section in FIG. 4. In the example illustrated in FIGS. 4 and 5, the three sensors 29 disposed in the area AR1 of the stator 11 face the mover 13, where the two sensors 29 on the diagonal line face the first target 31 and the second target 33, respectively, to detect the target. In this way, even when the mover 13 is located at any position on the stator 11, at least three or more sensors 29 are configured to face the mover 13. Note that the sensors 29 may be arranged in a pattern other than the above as long as the positions of the first mover 23 and the second mover 25 can be detected even when the mover 13 is located at any position on the stator 11. The controller 14 can individually detect the position on the XY plane, the rotation angle about the rotation axis AX, the height in the Z-axis direction, the inclination in the Ox and Oy directions, and the like of each of the first mover 23 and the second mover 25, based on the detection signal of each sensor 29. Furthermore, the controller 14 can detect a relative displacement (e.g., a relative angle, a relative position, or the like) between the first mover 23 and the second mover 25, based on the above detection result.

The type of the sensor 29 is not particularly limited, but in the present embodiment, for example, the first target 31 and the second target 33 are configured as linear scales, and the sensor 29 is configured as an optical sensor configured to optically detect the linear scales. Note that for example, the target may be formed of a magnet, and the sensor 29 may be a magnetic sensor configured to detect a magnetic field of the magnet. Furthermore, the sensor 29 may be a capacitive sensor or the like.

### 2. CONFIGURATION EXAMPLE OF MOVER AND SUBSTRATE SUPPORT

In the substrate transport system 1 described above, the mover 13 and the substrate support 21 can be configured in a wide variety of ways. Hereinafter, specific configuration examples of the mover 13 and the substrate support 21 will be described.

2-1. Case where First Mover and Second Mover Perform Rotating Operation

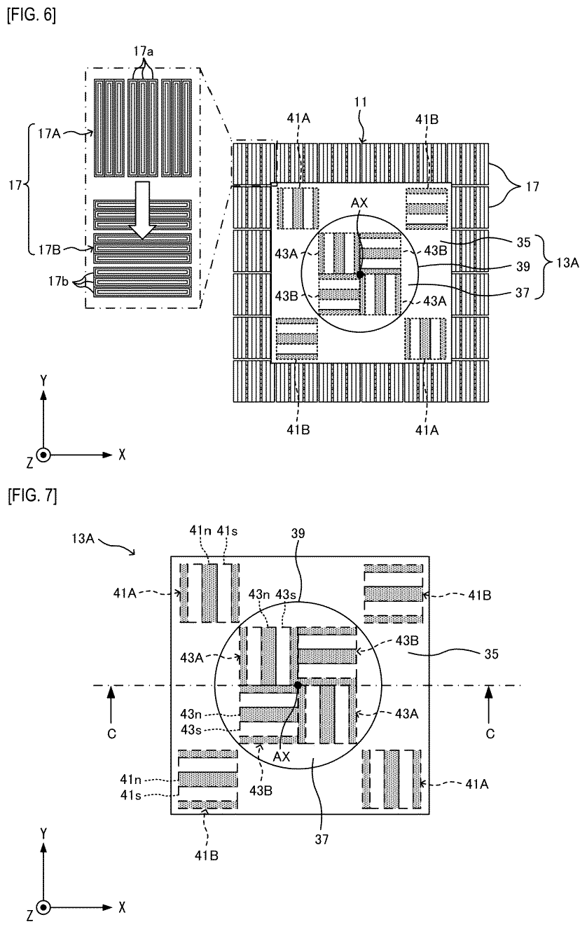

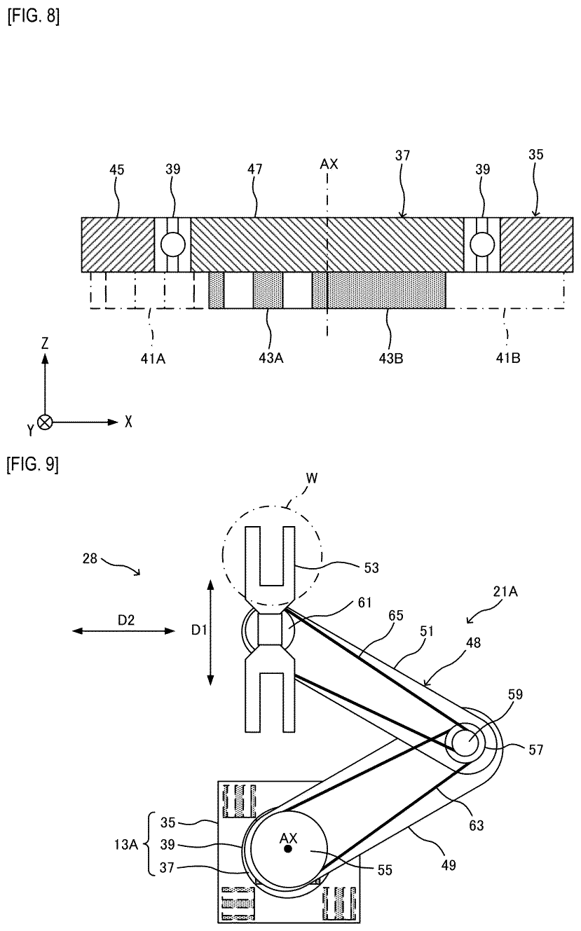

FIGS. 6 to 9 illustrate an example of the configurations of a mover 13A and a substrate support 21A in a case where the first mover and the second mover are configured to perform rotating operation. FIG. 6 is a top view illustrating an example of configurations of the mover 13A and the stator 11, FIG. 7 is a top view illustrating an example of a configuration of the mover 13A, FIG. 8 is a cross-sectional view corresponding to a C-C cross section in FIG. 7, and FIG. 9 is a top view illustrating an example of a configuration of the substrate support 21A.

As illustrated in FIG. 6, the stator 11 includes a plurality of coil units 17 arrayed in a lattice shape. As illustrated in an enlarged view in FIG. 6, the coil unit 17 is configured as a coil unit by stacking a coil group 17A and a coil group 17B in the Z-axis direction. The coil group 17A is configured by arranging a plurality of coils 17a elongated in the Y-axis direction in parallel in the X-axis direction. The coil group 17B is configured by arranging a plurality of coils 17b elongated in the X-axis direction in parallel in the Y-axis direction. In the example illustrated in FIG. 6, the coil group 17A is stacked on the upper side of the coil group 17B, but conversely, the coil group 17B may be stacked on the upper side of the coil group 17A.

As illustrated in FIGS. 6 and 7, the mover 13A includes a first mover 35 having a substantially quadrangular shape, a second mover 37 having a substantially circular shape, and a bearing 39. The first mover 35 (an example of a first mover) includes four first magnet units 41A and 41B (an example of a first magnet) on the lower side in the vicinity of four corners, and moves while floating above the stator 11. The first magnet unit 41A and the first magnet unit 41B have different orientations from each other. The first magnet unit 41A is configured by alternately arraying, in the X-axis direction, a permanent magnet 41n that is elongated in the Y-axis direction and has the side facing the stator 11 as an N pole, and a permanent magnet 41s that is elongated in the Y-axis direction and has the side facing the stator 11 as an S pole. The first magnet unit 41B is configured by alternately arraying, in the Y-axis direction, a permanent magnet 41n that is elongated in the X-axis direction and has the side facing the stator 11 as an N pole, and a permanent magnet 41s that is elongated in the X-axis direction and has the side facing the stator 11 as an S pole. The two first magnet units 41A are disposed on one diagonal line of the first mover 35, and the two first magnet units 41B are disposed on the other diagonal line of the first mover 35. Each of the first magnet units 41A and 41B is formed to have substantially the same size as the coil unit 17. Note that the first magnet units 41A and 41B may be configured as a Halbach array in which a different permanent magnet is inserted between the permanent magnets 41n and 41s such that the magnetizing direction is orthogonal to the magnetizing directions of the permanent magnets 41n and 41s.

The first mover 35 obtains a thrust in the X-axis direction by mutual action of a magnetic field by the coil group 17A of the coil unit 17 and a magnetic field by the first magnet unit 41A. Furthermore, the first mover 35 obtains a thrust in the Y-axis direction by mutual action of a magnetic field by the coil group 17B of the coil unit 17 and a magnetic field by the first magnet unit 41B. In addition, the first mover 35 obtains a thrust in the rotating direction about the rotation axis AX by a combination of the thrust in the X-axis direction and the thrust in the Y-axis direction. As a result, the first mover 35 is movable in the horizontal direction (each direction on the XY plane including the X-axis direction and the Y-axis direction) and is rotatable in the rotating direction about the rotation axis AX. In addition, the first mover 35 obtains buoyancy in the Z-axis direction by mutual action of a magnetic field by the coil unit 17 and magnetic fields by the first magnet units 41A and 41B. Therefore, by adjusting the current phase of the coil unit 17, the floating height in the Z-axis direction and the inclination in the ex and Oy directions can be adjusted.

The second mover 37 (an example of a second mover) includes four second magnet units 43A and 43B (an example of a second magnet) on the lower side, and moves while floating above the stator 11. The second magnet unit 43A and the second magnet unit 43B have different orientations from each other. The second magnet unit 43A is configured by alternately arraying, in the X-axis direction, a permanent magnet 43n that is elongated in the Y-axis direction and has the side facing the stator 11 as an N pole, and a permanent magnet 43s that is elongated in the Y-axis direction and has the side facing the stator 11 as an S pole. The second magnet unit 43B is configured by alternately arraying, in the Y-axis direction, a permanent magnet 43n that is elongated in the X-axis direction and has the side facing the stator 11 as an N pole, and a permanent magnet 43s that is elongated in the X-axis direction and has the side facing the stator 11 as an S pole. The four second magnet units 43A and 43B are alternately disposed so as to surround the periphery of the rotation axis AX. That is, the two second magnet units 43A are arranged point-symmetrically with the rotation axis AX as the center, the two second magnet units 43B are arranged point-symmetrically with the rotation axis AX as the center, and the two sets of second magnet units 43A and 43B are arranged point-symmetrically with the rotation axis AX as the center. Each of the second magnet units 43A and 43B is formed to have substantially the same size as the coil unit 17. Note that the second magnet units 43A and 43B may be configured as a Halbach array in which a different permanent magnet is inserted between the permanent magnets 43n and 43s such that the magnetizing direction is orthogonal to the magnetizing directions of the permanent magnets 43n and 43s.

The second mover 37 obtains the thrust in the rotating direction about the rotation axis AX by a combination of the thrust in the X-axis direction by mutual action between the magnetic field of the coil group 17A and the magnetic field of the second magnet unit 43A and the thrust in the Y-axis direction by mutual action between the magnetic field of the coil group 17B and the magnetic field of the second magnet unit 43B. Note that since the second mover 37 is integrally coupled to the first mover 35 by the bearing 39, the second mover 37 moves in the horizontal direction (each direction on the XY plane including the X-axis direction and the Y-axis direction) and the Z-axis direction together with the first mover 35.

As illustrated in FIG. 8, the first mover 35 has a first frame 45 (an example of a first frame) in which the first magnet units 41A and 41B are disposed on the coil unit 17 side. The second mover 37 has a second frame 47 (an example of a second frame) in which the second magnet units 43A and 43B are disposed on the coil unit 17 side. The bearing 39 (an example of a guide member) couples the first frame 45 and the second frame 47 to each other so as to be rotatable about the rotation axis AX. Note that although not illustrated, the first mover 35 includes the first target 31 to be detected by the plurality of sensors 29, and the second mover 37 includes the second target 33 to be detected by the plurality of sensors 29.

As illustrated in FIG. 9, the substrate support 21A includes an arm 48 configured to be extendable/contractible based on a relative operation between the first mover 35 and the second mover 37. The arm 48 includes a first arm 49, a second arm 51, a third arm 53, a first pulley 55, a second pulley 57, a third pulley 59, a fourth pulley 61, a first belt 63, and a second belt 65. The substrate W is supported by the third arm 53. Note that the first arm 49, the second arm 51, and the third arm 53 are examples of the plurality of link members, and the first pulley 55, the second pulley 57, the third pulley 59, and the fourth pulley 61 are examples of the transmission member.

A base end portion of the first arm 49 is fixed to the first mover 35, and a base end portion of the second arm 51 is rotatably coupled to a tip portion of the first arm 49. The first pulley 55 is fixed to the second mover 37 and is rotatably supported by the base end portion of the first arm 49. The second pulley 57 is fixed to the base end portion of the second arm 51 and is rotatably supported by the tip portion of the first arm 49. The third pulley 59 is fixed to the tip portion of the first arm 49 and is rotatably supported by the base end portion of the second arm 51. The fourth pulley 61 is rotatably supported by the tip portion of the second arm 51 and is fixed to the third arm 53. The first belt 63 is wound around the first pulley 55 and the second pulley 57. The second belt 65 is wound around the third pulley 59 and the fourth pulley 61. The ratio of the pitch circle diameters of the first pulley 55 and the second pulley 57 is 2:1. The ratio of the pitch circle diameters of the third pulley 59 and the fourth pulley 61 is 1:2. Note that in each configuration, the base end portion refers to a portion on the root side (the mover 13A side) in the extending direction of the arm 48, and the tip portion refers to a portion on the tip end side (the third arm 53 side) in the extending direction of the arm 48.

According to the above configuration, the arm 48 can adjust the position of the third arm 53, based on at least one of the presence or absence of rotation of each of the first mover 35 and the second mover 37, a rotating direction of each of the first mover 35 and the second mover 37, or a rotation speed of each of the first mover 35 and the second mover 37. For example, by fixing the second mover 37 so as not to rotate and rotating the first mover 35, the third arm 53 can be moved along an extending/contracting direction D1. The extending/contracting direction D1 is a radial direction having the rotation axis AX as the center. Furthermore, by rotating each of the first mover 35 and the second mover 37 in the same rotating direction at the same rotation speed, the arm 48 can be rotated about the rotation axis AX without changing the entire posture. In addition, by rotating each of the first mover 35 and the second mover 37 in any directions at different rotation speeds, the arm 48 can be rotated about the rotation axis AX while being extended/contracted.

Note that the configuration of the arm 48 described above is an example, and a configuration other than the above may be adopted. In addition, the stator 11, the first mover 35, the second mover 37, the bearing 39, and the substrate support 21A constitute a substrate transport device 28.

2-2. Case where First Mover and Second Mover Perform Linear Operation

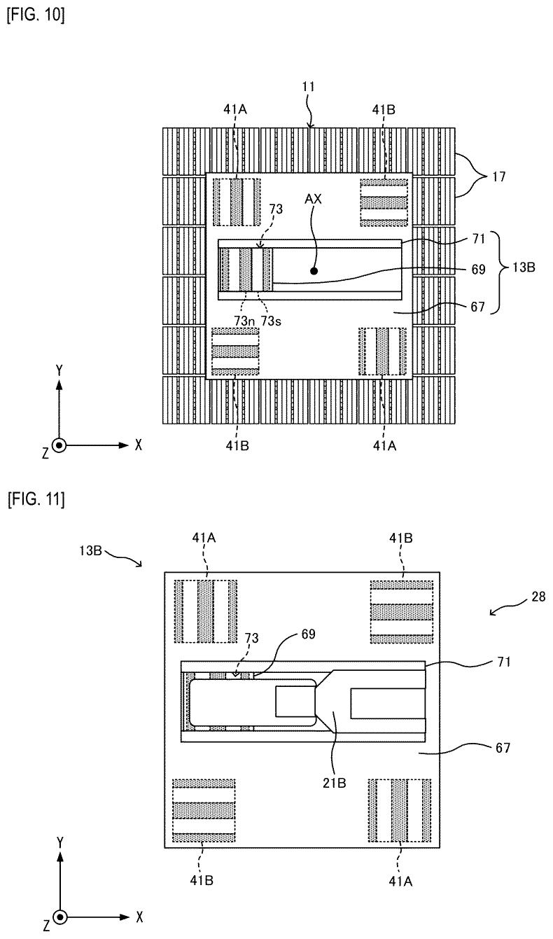

FIGS. 10 and 11 illustrate an example of the configurations of a mover 13B and a substrate support 21B in a case where the first mover and the second mover are configured to perform linear operation. FIG. 10 is a top view illustrating an example of the configurations of the mover 13B and the stator 11, and FIG. 11 is a top view illustrating an example of the configurations of the mover 13B and the substrate support 21B.

As illustrated in FIGS. 10 and 11, the mover 13B includes a first mover 67 having a substantially quadrangular shape, a second mover 69 having a substantially quadrangular shape, and a linear motion guide 71. The first mover 67 (an example of a first mover) is formed to a quadrangular shape larger than the second mover 69, and is disposed so as to surround the periphery of the second mover 69. The first mover 67 includes four first magnet units 41A and 41B on the lower side in the vicinity of four corners, similarly to the first mover 35 described above.

The linear motion guide 71 (an example of a guide member) guides the first mover 67 and the second mover 69 so as to be relatively operable. The linear motion guide 71 regulates a relative operating direction of the first mover 67 and the second mover 69 to a linear direction. At least one of the first mover 67 or the second mover 69 moves along the linear direction regulated by the linear motion guide 71.

The second mover 69 (an example of a second mover) includes, for example, one second magnet unit 73 (an example of a second magnet) on the lower side. The second magnet unit 73 is configured by alternately arraying, in the X-axis direction, a permanent magnet 73n that is elongated in the Y-axis direction and has the side facing the stator 11 as an N pole, and a permanent magnet 73s that is elongated in the Y-axis direction and has the side facing the stator 11 as an S pole. The second magnet unit 73 is formed to substantially the same size as the coil unit 17. Note that the second magnet unit 73 may be configured as a Halbach array in which a different permanent magnet is inserted between the permanent magnets 73n and 73s such that the magnetizing direction is orthogonal to the magnetizing directions of the permanent magnets 73n and 73s.

The second mover 69 obtains a thrust in the X-axis direction by mutual action of a magnetic field by the coil group 17A of the coil unit 17 and a magnetic field by the second magnet unit 73. Furthermore, when the first mover 67 is rotated 90° in the rotating direction about the rotation axis AX from the state illustrated in FIG. 10, the second mover 69 obtains the thrust in the Y-axis direction by the mutual action between the magnetic field by the coil group 17B of the coil unit 17 and the magnetic field by the second magnet unit 73. That is, the second mover 69 is movable in the horizontal direction (each direction on the XY plane including the X-axis direction and the Y-axis direction) by the rotating operation of the first mover 67. Note that although not illustrated, the first mover 67 includes the first target 31 to be detected by the plurality of sensors 29, and the second mover 69 includes the second target 33 to be detected by the plurality of sensors 29.

As illustrated in FIG. 11, the substrate support 21B is configured as an arm that can support the substrate W. The substrate support 21B is connected to the second mover 69 and moves in a linear direction along the linear motion guide 71 together with the second mover 69. Note that the stator 11, the first mover 67, the second mover 69, the linear motion guide 71, and the substrate support 21B constitute the substrate transport device 28.

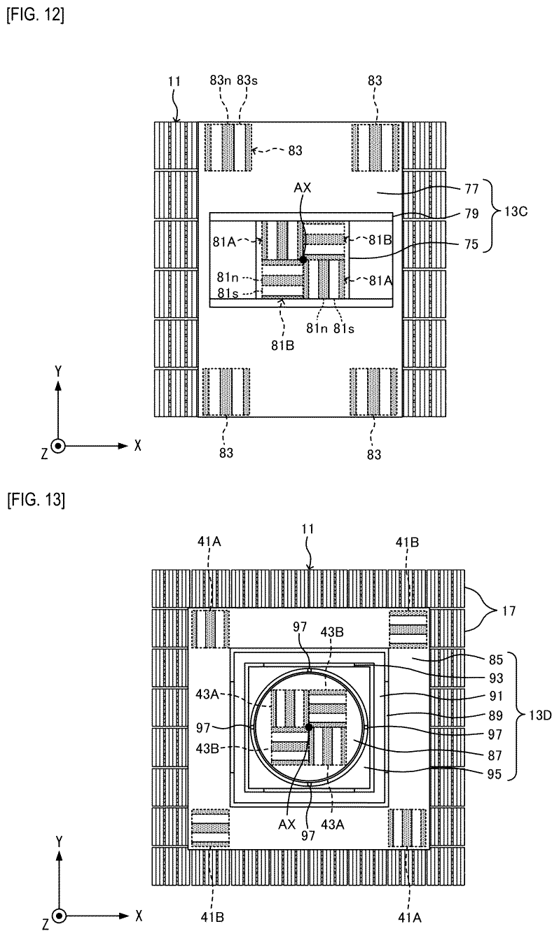

In the above description, the first mover 67 is disposed so as to surround the periphery of the second mover 69, but conversely, the second mover may be disposed so as to surround the periphery of the first mover. FIG. 12 shows an example of the configuration of the mover 13C in this case. FIG. 12 is a top view illustrating an example of the configurations of the mover 13C and the stator 11.

As illustrated in FIG. 12, the mover 13C includes a first mover 75 having a substantially quadrangular shape, a second mover 77 having a substantially quadrangular shape, and a linear motion guide 79. The second mover 77 is formed in a quadrangular shape larger than the first mover 75, and is disposed so as to surround the periphery of the first mover 75.

The first mover 75 (an example of a first mover) includes four first magnet units 81A and 81B (an example of a first magnet) on the lower side, and moves while floating above the stator 11. The first magnet unit 81A and the first magnet unit 81B have different orientations from each other. The first magnet unit 81A is configured by alternately arraying, in the X-axis direction, a permanent magnet 81n that is elongated in the Y-axis direction and has the side facing the stator 11 as an N pole, and a permanent magnet 81s that is elongated in the Y-axis direction and has the side facing the stator 11 as an S pole. The first magnet unit 81B is configured by alternately arraying, in the Y-axis direction, a permanent magnet 81n that is elongated in the X-axis direction and has the side facing the stator 11 as an N pole, and a permanent magnet 81s that is elongated in the X-axis direction and has the side facing the stator 11 as an S pole. The four first magnet units 81A and 81B are alternately disposed so as to surround the rotation axis AX. As a result, the first mover 75 obtains a thrust in the X-axis direction, the Y-axis direction, the rotating direction about the rotation axis AX, and the like.

The linear motion guide 79 (an example of a guide member) guides the first mover 75 and the second mover 77 so as to be relatively operable. The linear motion guide 79 regulates a relative operating direction of the first mover 75 and the second mover 77 to a linear direction. At least one of the first mover 75 or the second mover 77 moves along the linear direction regulated by the linear motion guide 79.

The second mover 77 (an example of a second mover) includes four second magnet units 83 (an example of a second magnet) on the lower side in the vicinity of four corners, and moves while floating above the stator 11. The second magnet unit 83 is configured by alternately arraying, in the X-axis direction, a permanent magnet 83n that is elongated in the Y-axis direction and has the side facing the stator 11 as an N pole, and a permanent magnet 83s that is elongated in the Y-axis direction and has the side facing the stator 11 as an S pole. The second mover 77 obtains a thrust in the X-axis direction by mutual action of the magnetic field by the coil group 17A of the coil unit 17 and the magnetic field by the second magnet unit 83. Furthermore, when the first mover 75 is rotated 90° in the rotating direction about the rotation axis AX from the state illustrated in FIG. 12, the second mover 77 obtains the thrust in the Y-axis direction by the mutual action between the magnetic field by the coil group 17B of the coil unit 17 and the magnetic field by the second magnet unit 83. That is, the second mover 77 is movable in the horizontal direction (each direction on the XY plane including the X-axis direction and the Y-axis direction) by the rotating operation of the first mover 75.

Although not illustrated, in the above configuration, the substrate support is connected to the second mover 77 and moves in the linear direction along the linear motion guide 79 together with the second mover 77. Note that although not illustrated, the first mover 75 includes the first target 31 to be detected by the plurality of sensors 29, and the second mover 77 includes the second target 33 to be detected by the plurality of sensors 29.

2-3. Case where First Mover and Second Mover are Coupled by Elastic Body

FIG. 13 illustrates an example of a configuration of a mover 13D in a case where the first mover and the second mover are coupled by an elastic body. FIG. 13 is a top view illustrating an example of a configuration of the mover 13D.

As illustrated in FIG. 13, the mover 13D includes a first mover 85, a second mover 87, a linear motion guide 89, a first frame 91, a linear motion guide 93, a second frame 95, and an elastic body 97. The second mover 87 has a substantially circular shape, and the first mover 85 has a substantially quadrangular shape. The first mover 85 (an example of a first mover) is disposed so as to surround the periphery of the second mover 87. The first mover 85 includes four first magnet units 41A and 41B on the lower side in the vicinity of four corners, similarly to the first mover 35 described above. Further, the second mover 87 (an example of a second mover) includes four second magnet units 43A and 43B alternately disposed so as to surround the rotation axis AX, similarly to the second mover 37 described above.

The first frame 91 is a frame having a substantially quadrangular frame shape, and is disposed on the inner side of the first mover 85 by way of the linear motion guide 89. At least one of the first mover 85 or the first frame 91 moves along the linear direction (Y-axis direction in FIG. 13) regulated by linear motion guide 89. The second frame 95 is a frame-shaped frame having a substantially quadrangular outer periphery and a substantially circular inner periphery, and is disposed on the inner side of the first frame 91 by way of the linear motion guide 93. At least one of the first frame 91 or the second frame 95 moves along the linear direction (X-axis direction in FIG. 13) regulated by the linear motion guide 93. The second mover 87 is disposed on the inner side of the second frame 95 by way of the elastic body 97. The elastic body 97 relatively operably couples the first mover 85 and the second mover 87 by relatively operably coupling the second frame 95 and the second mover 87. The elastic bodies 97 are, for example, components having elasticity such as a spring, and are disposed at a plurality of locations (e.g., 4 locations every) 90° around the second mover 87. Note that the elastic bodies 97 may be disposed in a manner other than the above. In addition, the elastic body may be configured, for example, as one component in an annular shape. Note that although not illustrated, the first mover 85 includes the first target 31 to be detected by the plurality of sensors 29, and the second mover 87 includes the second target 33 to be detected by the plurality of sensors 29.

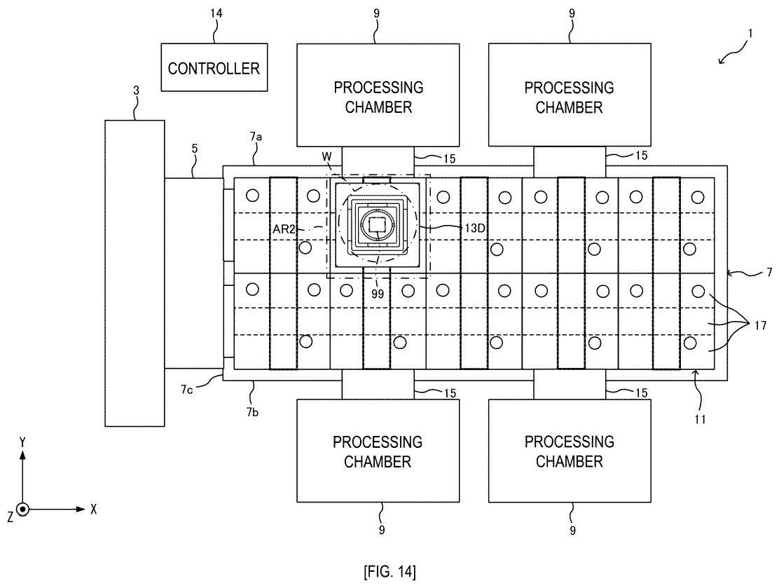

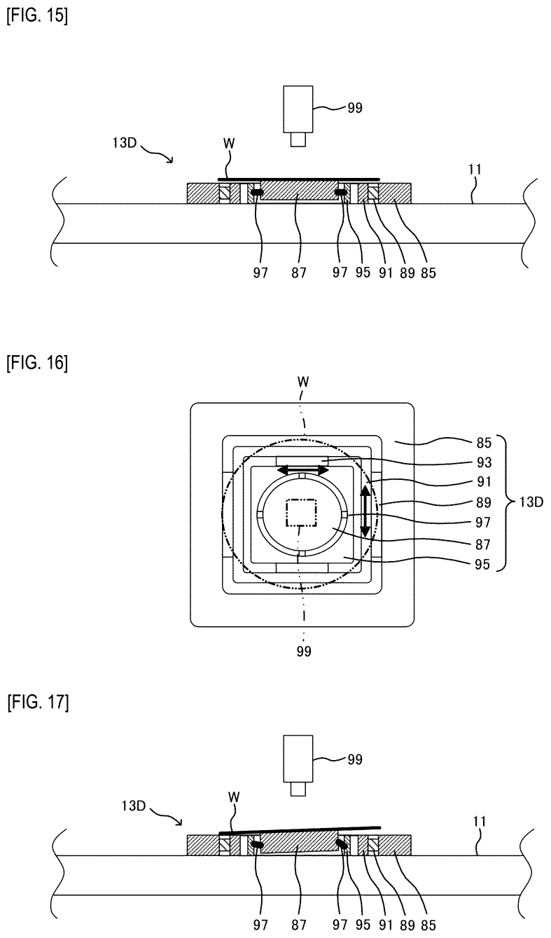

In the mover 13D, the elastic body 97 has flexibility in, for example, the Z-axis direction. A utilization example of the mover 13D configured as described above will be described with reference to FIGS. 14 to 17. Note that in FIGS. 14 to 17, the substrate support is not provided, and the substrate W is placed on the second mover 87. For example, when the substrate transport system 1 is used in a semiconductor manufacturing step, it is conceivable to inspect the substrate W in the step. For example, a foreign material inspection or the like using a camera image is performed. In the example illustrated in FIG. 14, an inspection area AR2 is set in front of a specific processing chamber 9 in the vacuum transport chamber 7, and an inspection device 99 is installed above the inspection area AR2. The inspection device 99 is, for example, a camera or the like. In the inspection step, the substrate W is transported to below the inspection device 99 by the mover 13D, imaged by the inspection device 99 in a positioned state, and subjected to confirmation of foreign materials. At this time, for fine adjustment of the position with respect to the inspection device 99, fine alignment in the horizontal direction (each direction on the XY plane including the X-axis direction and the Y-axis direction) or the Z-axis direction, or fine adjustment of the inclination in the ex direction or the Oy direction may be performed. An example of the operation of this fine adjustment is illustrated in FIGS. 15 to 17.

First, as illustrated in FIG. 15, the first mover 85 is released from floating and is seated on the stator 11. Since micro-vibration is generated in the Z-axis direction in the floating state, the substrate W can be stabilized by seating the stator 11. In this case, the dimensions of the respective components of the mover 13D are set so that the second mover 87 does not come into contact with the stator 11.

In this state, as illustrated in FIG. 16, the thrust in the horizontal direction (each direction on the XY plane including the X-axis direction and the Y-axis direction) is applied to the second mover 87. Thus, the linear motion guides 89 and 93 slide and the first frame 91 and the second frame 95 linearly move, respectively, whereby the substrate W is positioned in the horizontal direction.

Furthermore, as illustrated in FIG. 17, by applying the thrust in the Z-axis direction to the second mover 87, the elastic body 97 is deformed, and the position in the Z-axis direction and the inclinations in the ex direction and the Oy direction are adjusted. In this case, although the second mover 87 is in the floating state, only the second mover 87 and the substrate Ware operated, so that the mass and the moment of inertia are reduced as compared with the case where the entire mover 13D is in the floating state, and the vibration level can be reduced.

In the above description, the elastic body 97 has flexibility in the Z-axis direction, but in addition to or in place of this, the elastic body 97 may have flexibility in the X-axis direction or the Y-axis direction. In this case, at least one of the linear motion guide 89 or 93 can be omitted.

2-4. Case where Mover is Configured to Straddle Opening/Closing Door

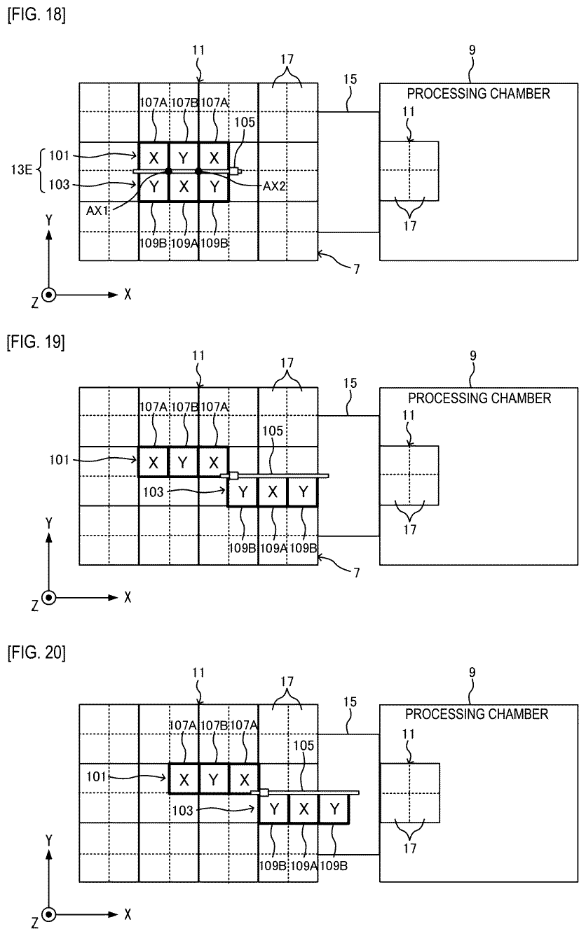

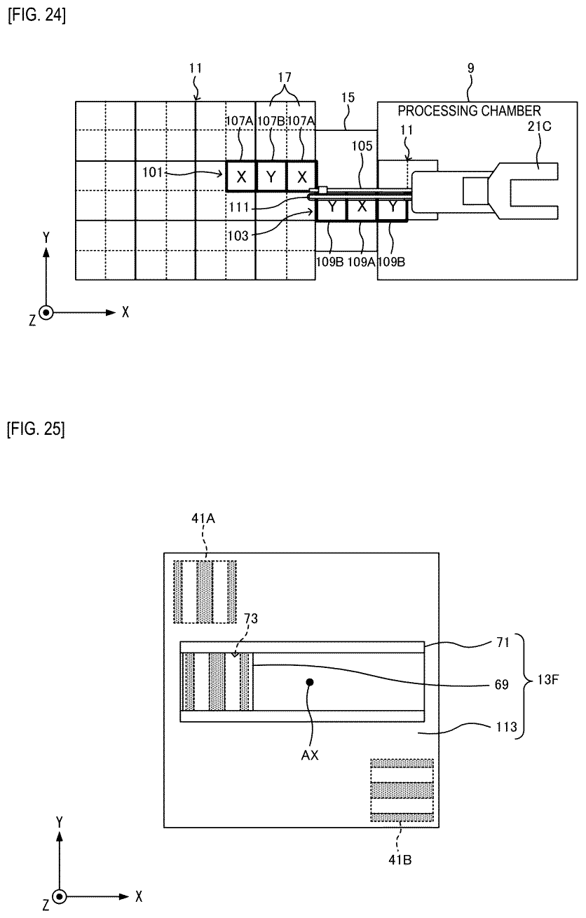

When the stator 11 is installed in both the vacuum transport chamber 7 and the processing chamber 9, the opening portion of the processing chamber 9 is opened/closed by the opening/closing door 15, and hence the stator 11 cannot be installed. Therefore, the mover may be configured to straddle the opening/closing door 15. FIGS. 18 to 24 illustrate an example of the configuration of the mover 13E and the substrate support 21C that are configured to straddle the opening/closing door 15. FIGS. 18 to 22 are diagrams conceptually illustrating an example of an operation in which the mover 13E straddles the opening/closing door 15. FIGS. 23 and 24 are diagrams illustrating an example of a configuration of the substrate support 21C. Note that in FIGS. 18 to 22, the illustration of the substrate support 21C is omitted.

As illustrated in FIG. 18, the stator 11 including a plurality of coil units 17 is provided at least in the vicinity of the opening/closing door 15 inside the processing chamber 9. On the other hand, the stator 11 is not provided in the opening/closing door 15 disposed between the vacuum transport chamber 7 and the processing chamber 9. The mover 13E includes a first mover 101, a second mover 103, and a linear motion guide 105.

The first mover 101 (an example of a first mover) includes, for example, three first magnet units 107A and 107B (an example of a first magnet), and moves while floating above the stator 11. In this example, the first magnet unit 107B is disposed between two first magnet units 107A. The first magnet unit 107A is a magnet unit that contributes to the thrust in the X-axis direction. Although not illustrated, the first magnet unit 107A is configured by alternately arraying, in the X-axis direction, a permanent magnet that is elongated in the Y-axis direction and has the side facing the stator 11 as an N pole, and a permanent magnet that is elongated in the Y-axis direction and has the side facing the stator 11 as an S pole. The first magnet unit 107B is a magnet unit that contributes to the thrust in the Y-axis direction. Although not illustrated, the first magnet unit 107B is configured by alternately arraying, in the Y-axis direction, a permanent magnet that is elongated in the X-axis direction and has the side facing the stator 11 as an N pole, and a permanent magnet that is elongated in the X-axis direction and has the side facing the stator 11 as an S pole. The first magnet units 107A and 107B are formed to have substantially the same size as the coil unit 17.

The second mover 103 (an example of a second mover) includes, for example, three second magnet units 109A and 109B (an example of a second magnet), and moves while floating above the stator 11. In this example, the second magnet unit 109A is disposed between two second magnet units 109B. The second magnet unit 109A is configured similarly to the first magnet unit 107A, and is a magnet unit that contributes to thrust in the X-axis direction. The second magnet unit 109B is configured similarly to the first magnet unit 107B, and is a magnet unit that contributes to the thrust in the Y-axis direction. The second magnet units 109A and 109B are formed to have substantially the same size as the coil unit 17.

The linear motion guide 105 (an example of a guide member) guides the first mover 101 and the second mover 103 so as to be relatively operable. The linear motion guide 105 regulates a relative operating direction of the first mover 101 and the second mover 103 to a linear direction. At least one of the first mover 101 or the second mover 103 moves along the linear direction regulated by the linear motion guide 105.

The mover 13E obtains the thrust in the X-axis direction by mutual action of a magnetic field by the coil group 17A of the coil unit 17 and magnetic fields by the first magnet unit 107A and the second magnet unit 109A. Furthermore, the mover 13E obtains a thrust in the Y-axis direction by mutual action of a magnetic field by the coil group 17B of the coil unit 17 and magnetic fields by the first magnet unit 107B and the second magnet unit 109B. Furthermore, the mover 13E obtains a thrust in the rotating direction about the rotation axis AX1 or the rotation axis AX2 by a combination of the thrust in the X-axis direction and the thrust in the Y-axis direction. As a result, the mover 13E is movable in the horizontal direction (each direction on the XY plane including the X-axis direction and the Y-axis direction) and is rotatable in the rotating direction about the rotation axis AX1 or AX2. Furthermore, the mover 13E obtains buoyancy in the Z-axis direction by mutual action of a magnetic field by the coil unit 17 and magnetic fields by the first magnet units 107A and 107B and the second magnet units 109A and 109B. Therefore, the mover 13E can adjust the floating height in the Z-axis direction and the inclination in the Ox and Oy directions by adjusting the current phase of the coil unit 17.

Note that although not illustrated, the stator 11 includes a plurality of sensors 29 for detecting the positions of the first mover 101 and the second mover 103. Furthermore, the first mover 101 includes a first target 31 to be detected by the plurality of sensors 29, and the second mover 103 includes a second target 33 to be detected by the plurality of sensors 29.

As illustrated in FIG. 18, the mover 13E is moved to a position facing the processing chamber 9 in a state where the first mover 101 and the second mover 103 are relatively stationary, and is stopped at a position in the vicinity of the opening/closing door 15. When moving, for example, the first magnet unit 107A and the second magnet unit 109B are arranged in the Y-axis direction, and the first magnet unit 107B and the second magnet unit 109A are arranged in the Y-axis direction. In the example illustrated in FIG. 18, for example, the mover 13E is stopped at a position away from the opening/closing door 15 by the length of three magnet units of the second mover 103 in the X-axis direction (three coil units 17). Note that the dimension of the opening/closing door 15 in the X-axis direction is assumed to be equivalent to two coil units 17. The opening/closing door 15 is in an open state.

Next, as illustrated in FIG. 19, in a state where the first mover 101 is stopped, the second mover 103 is moved toward the processing chamber 9 in the X-axis direction via the linear motion guide 105. In the example illustrated in FIG. 19, the second mover 103 is moved toward the processing chamber 9 side by, for example, the amount of three coil units 17.

Next, as illustrated in FIG. 20, in a state where the second mover 103 has advanced toward the processing chamber 9 side with respect to the first mover 101, the entire mover 13E is moved toward the processing chamber 9 in the X-axis direction. In the example illustrated in FIG. 20, the mover 13E is moved toward the processing chamber 9 side by, for example, the amount of one coil unit 17. As a result, the second mover 103 is in a state where the two second magnet units 109A and 109B face the coil unit 17 of the vacuum transport chamber 7 and the one second magnet unit 109B does not face the coil unit 17.

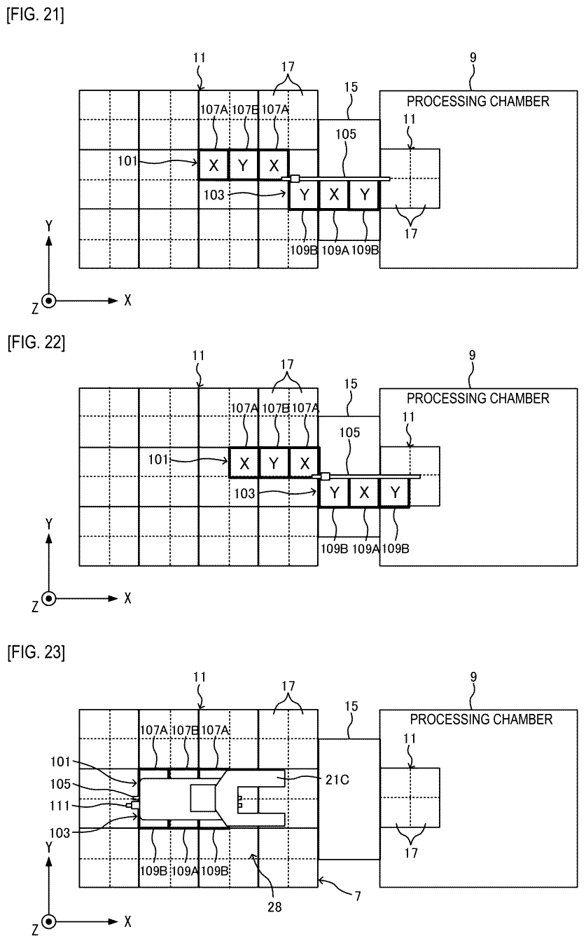

Next, as illustrated in FIG. 21, the entire mover 13E is further moved toward the processing chamber 9 in the X-axis direction. In the example illustrated in FIG. 21, the mover 13E is further moved toward the processing chamber 9 side by, for example, the amount of one coil unit 17. As a result, the second mover 103 is in a state where the one second magnet unit 109B faces the coil unit 17 of the vacuum transport chamber 7 and the two second magnet units 109A and 109B do not face the coil unit 17.

Next, as illustrated in FIG. 22, the entire mover 13E is further moved toward the processing chamber 9 in the X-axis direction. In the example illustrated in FIG. 22, the mover 13E is further moved to the processing chamber 9 side by, for example, the amount of one coil unit 17. As a result, the second mover 103 is in a state where the one second magnet unit 109B faces the coil unit 17 of the processing chamber 9, and the two second magnet units 109A and 109B do not face the coil unit 17.

As described above, in the vacuum transport chamber 7, the mover 13E is moved to a position facing the processing chamber 9 in a state where the first mover 101 and the second mover 103 are relatively stationary. Then, the first mover 101 and the second mover 103 are relatively operated, and the second mover 103 straddles the opened opening/closing door 15. As a result, as illustrated in FIGS. 23 and 24, the substrate support 21C connected to the second mover 103 enters the processing chamber 9. At this time, at least one magnet unit of the three magnet units constituting the second mover 103 is configured to face the coil unit 17 while the second mover 103 straddles the opening/closing door 15. In other words, at least four magnet units among the three magnet units constituting the first mover 101 and the three magnet units constituting the second mover 103 (six magnet units in total) are configured to face the coil unit 17 at four or more locations while straddling the opening/closing door 15. This suppresses the toppling and the like of the mover 13E, and the substrate W can be delivered in a stable posture.

Note that although the second mover 103 straddles the opening/closing door 15 in the above description, the first mover 101 may be operated to straddle the opening/closing door 15. Furthermore, in the above description, each of the first mover 101 and the second mover 103 is configured by three magnet units, but each may be configured by, for example, two magnet units. For example, the first mover 101 may be configured by two first magnet units 107A and 107B, and the second mover 103 may be configured by two second magnet units 109A and 109B. In this case, by setting the dimension of the opening/closing door 15 in the X-axis direction to, for example, one coil unit 17, at least three magnet units can be configured to face the coil unit 17 at three or more locations while the first mover 101 or the second mover 103 straddles the opening/closing door 15. This suppresses the toppling and the like of the mover, and the substrate W can be delivered in a stable posture.

FIGS. 23 and 24 illustrate an example of the configuration of the substrate support 21C. FIG. 23 corresponds to FIG. 18, and FIG. 24 corresponds to FIG. 22. As illustrated in FIGS. 23 and 24, the substrate support 21C is configured as an arm that can support the substrate W. The substrate support 21C is connected to the second mover 103 and moves in a linear direction along the linear motion guide 105 together with the second mover 103. In the example illustrated in FIGS. 23 and 24, the substrate support 21C is connected to the second mover 103 via the extending/contracting mechanism 111. The extending/contracting mechanism 111 is configured to extend according to the distance that the second mover 103 is separated from the first mover 101. Accordingly, as illustrated in FIG. 24, the substrate support 21C can be advanced to the more inner side of the processing chamber 9. Note that the stator 11, the first mover 101, the second mover 103, the linear motion guide 105, and the substrate support 21C constitute the substrate transport device 28.

### 3. EFFECTS OF EMBODIMENT

As described above, in the substrate transport device 28 according to the present embodiment, the guide member (bearings 27 and 39, linear motion guides 71, 79, and 105) guides the first mover (23, 35, 67, 75, 85, and 101) and the second mover (25, 37, 69, 77, 87, and 103) in a relatively operable manner. A substrate support (21, 21A, 21B, and 21C) for supporting the substrate W is connected to at least one of the first mover or the second mover. Accordingly, the first mover and the second mover are relatively operated, and thus the substrate support can be operated and the supporting position of the substrate W can be moved. For example, when the first mover and the second mover move in the vacuum transport chamber 7, the substrate support can be pulled into the mover, and when the substrate W is delivered in the processing chamber 9, the substrate support can be protruded to the outer side of the mover. Since the first mover and the second mover can be moved in a state where the substrate support is contracted, the installation area of the stator 11 (vacuum transport chamber 7) can be reduced. Further, since the first mover and the second mover can be rotated in a small radius, the transport efficiency of the substrate W can be improved. In addition, since the substrate support can be operated by the relative operation between the first mover and the second mover, a power source for operating the substrate support becomes unnecessary. That is, the planar motor constituted by the stator 11, the first mover, and the second mover can also be utilized as a power source of the substrate support.

Furthermore, in the present embodiment, the frames of the first mover and the second mover may be coupled to each other by the guide member. In this case, the coupling can be firmly performed without inhibiting the magnetic field generated from the magnet.

Moreover, in the present embodiment, the first mover and the second mover may move on the stator 11 in a relatively stationary state. In this case, when the mover (13, 13A, 13B, 13C, 13D, and 13E) moves, the substrate support is not operated, and the supporting position of the substrate W with respect to the first mover or the second mover can be kept unchanged. This enables the substrate W to be transported in a stable state.

In the present embodiment, the guide member may regulate a relative operating direction of the first mover and the second mover, and at least one of the first mover or the second mover may move in a direction regulated by the guide member. In this case, the guide member can serve as a component for guiding the first mover and the second mover and a component for regulating the respective operating directions. This reduces the number of components.

Furthermore, in the present embodiment, the first mover (23, 35, 67, and 85) may be disposed so as to surround the periphery of the second mover (25, 37, 69, and 87). In this case, it is possible to downsize the mover as compared with a case where the first mover and the second mover are separately arranged on the outer side of each mover.

In the present embodiment, the bearing (27 and 39) may regulate the operating direction to the rotating direction about the rotation axis AX, and at least one of the first mover (23 and 35) or the second mover (25 and 37) may rotate about the rotation axis AX. In this case, the substrate support (21 and 21A) can be operated using the relative rotating operation by the first mover and the second mover, and the supporting position of the substrate W can be changed.

Furthermore, in the present embodiment, the substrate support (21A) may be configured such that the position with respect to the first mover or the second mover is adjusted based on at least one of the rotating directions of the first mover (35) and the second mover (37) or the rotation speeds of the first mover and the second mover. In this case, the substrate support is operated by controlling the rotating directions and the rotation speeds of the first mover and the second mover, and the supporting position of the substrate W can be adjusted.

In the present embodiment, the linear motion guide (71, 79, and 105) may regulate the operating direction to the linear direction, and the first mover (67, 75, 85, and 101) or the second mover (69, 77, 87, and 103) may move in the linear direction. In this case, the substrate support (21B and 21C) can be operated using the relative linear operation by the first mover and the second mover, and the supporting position of the substrate W can be changed.

Furthermore, in the present embodiment, in the stator 11, the coil unit 17 in the region facing the first mover and the coil unit 17 in the region facing the second mover may each have the current independently controlled. In this case, the operation of the first mover and the operation of the second mover can be independently controlled.

In the present embodiment, one mover of the first mover and the second mover may have two or more magnet units having different orientations from each other, and the other mover may have one or more magnet units. In this case, the mover having two or more magnet units with mutually different orientations can be moved in the X-axis direction, the Y-axis direction, and the rotating direction about the Z-axis, and the mover having one or more magnet units can be moved in the X-axis direction or the Y-axis direction. Therefore, a planar motor that can be controlled to at least three degrees of freedom can be configured.

Furthermore, in the present embodiment, the substrate support (21A) may include an arm 48 including a plurality of arms (49, 51, and 53) and a plurality of pulleys (55, 57, 59, and 61), and configured to be extendable/contractible based on a relative operation of the first mover (35) and the second mover (37). In this case, the arm 48 of the substrate support can be extended/contracted by relatively operating the first mover and the second mover. Thus, when the mover 13E moves, the arm 48 is contracted to pull in the substrate W, and when the substrate W is delivered, the arm 48 is extended to protrude the substrate W.

Furthermore, in the present embodiment, the stator 11 may include a plurality of sensors 29 configured to detect the positions of the first mover and the second mover, the first mover may include a first target 31 to be detected by the plurality of sensors 29, and the second mover may include a second target 33 to be detected by the plurality of sensors 29. In this case, the positions of the first mover and the second mover can be individually detected by the plurality of sensors 29 included in the stator 11. Accordingly, the operation of the first mover and the operation of the second mover can be controlled independently of each other. In addition, a sensor that detects the position of the first mover and a sensor that detects the position of the second mover can be shared.

Furthermore, in the present embodiment, the first mover (85) and the second mover (87) may be coupled to be relatively operable by an elastic body 97. In this case, the flexibility of the elastic body 97 can be used to perform fine alignment and fine adjustment of the inclination of the substrate W.

In addition, in the present embodiment, the mover (13E) may be configured such that the first mover (101) or the second mover (103) straddles the opened opening/closing door 15. In this case, even when the stator 11 is not provided at the portion of the opening/closing door 15 of the processing chamber 9, the substrate support (21C) can be advanced into the processing chamber 9 to deliver the substrate W. Furthermore, since the coil unit 17 and the magnet unit are configured to face each other at three or more locations when the first mover or the second mover straddles the opened opening/closing door 15, it is possible to suppress the toppling and the like of the mover (13E), and the substrate W can be delivered in a stable posture.

### 4. MODIFIED EXAMPLES

The embodiment of the present disclosure is not limited to the above, and various modifications are possible without departing from the spirit and technical ideas of the present disclosure.

In the above embodiment, for example, in the mover 13B illustrated in FIG. 10, a case where the first mover 67 includes the four first magnet units 41A and 41B has been described, but the configuration may be further simplified. That is, one mover of the first mover and the second mover may include two or more magnet units having different orientations from each other, and the other mover may include one or more magnet units.

FIG. 25 illustrates an example of a configuration of a mover 13F of the present modified example. As illustrated in FIG. 25, the mover 13F includes a first mover 113, a second mover 69, and a linear motion guide 71. The first mover 113 (an example of a first mover or one mover) includes two first magnet units 41A and 41B (an example of a first magnet) having different orientations from each other on a diagonal line. The second mover 69 (an example of the other mover) includes one second magnet unit 73 (example of a second magnet). Since the magnet arrangement of the first magnet units 41A and 41B and the second magnet unit 73, and the configurations of the second mover 69 and the linear motion guide 71 are similar to those in FIGS. 10 and 11 described above, the description thereof will be omitted.

The first mover 113 obtains the thrust in the X-axis direction and the Y-axis direction by the mutual action between the magnetic field by the coil unit 17 and the magnetic fields by the first magnet units 41A and 41B. In addition, the first mover 113 obtains a thrust in the rotating direction about the rotation axis AX by a combination of the thrust in the X-axis direction and the thrust in the Y-axis direction. As a result, the first mover 113 is movable in the horizontal direction (each direction on the XY plane including the X-axis direction and the Y-axis direction) and is rotatable in the rotating direction about the rotation axis AX. In addition, the second mover 69 obtains the thrust in the linear direction by the mutual action between the magnetic field by the coil unit 17 and the magnetic field by the second magnet unit 73. Therefore, according to the present modified example, a planar motor that can be controlled in at least three degrees of freedom can be configured with a minimum magnet configuration.

Furthermore, in the above embodiment, for example, in the mover 13C illustrated in FIG. 12, a case where the first mover 75 includes the four first magnet units 81A and 81B alternately arranged so as to surround the periphery of the rotation axis AX has been described, but the configuration may be further simplified. That is, one mover of the first mover and the second mover may include two or more magnet units having different orientations from each other, the other mover may include one or more magnet units, and the two or more magnets having different orientations from each other may be arranged point-symmetrically about the rotation axis of the one mover.

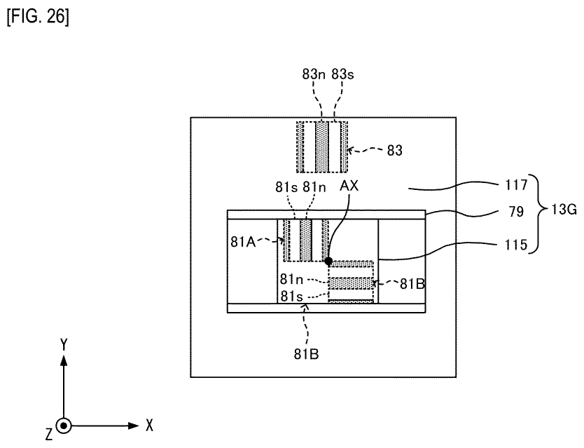

FIG. 26 illustrates an example of a configuration of a mover 13G of the present modified example. As illustrated in FIG. 26, the mover 13G includes a first mover 115, a second mover 117, and a linear motion guide 79. The first mover 115 (an example of a first mover or one mover) includes two first magnet units 81A and 81B (an example of a first magnet) having different orientations from each other. The two first magnet units 81A and 81B are arranged point-symmetrically about the rotation axis AX. The second mover 117 (an example of a second mover or the other mover) includes one second magnet unit 83 (an example of a second magnet). The magnet arrangement of the first magnet units 81A and 81B and the second magnet unit 83, and the configuration of the linear motion guide 79 are similar to those in FIG. 12 described above, and thus the description thereof will be omitted.

The first mover 115 obtains the thrust in the X-axis direction and the Y-axis direction by the mutual action between the magnetic field by the coil unit 17 and the magnetic fields by the first magnet units 81A and 81B. In addition, the first mover 115 obtains a thrust in the rotating direction about the rotation axis AX by a combination of the thrust in the X-axis direction and the thrust in the Y-axis direction. As a result, the first mover 115 is movable in the horizontal direction (each direction on the XY plane including the X-axis direction and the Y-axis direction) and is rotatable in the rotating direction about the rotation axis AX. In addition, the second mover 117 obtains the thrust in the linear direction by the mutual action between the magnetic field by the coil unit 17 and the magnetic field by the second magnet unit 83. Therefore, according to the present modified example, a planar motor that can be controlled in at least three degrees of freedom can be configured with a minimum magnet configuration.

In the above description, when “perpendicular”, “parallel”, “planar”, and the like are used, the meanings are not construed strictly. That is, “perpendicular”, “parallel”, and “planar” mean “substantially perpendicular”, “substantially parallel”, and “substantially planar”, respectively, with allowance for design and manufacturing tolerances and errors.

In the above description, when “the same”, “identical”, “equal”, “different”, and the like are used in reference to the external dimensions and sizes, shapes, positions, or the like, the meanings are not construed strictly. That is, “the same”, “identical”, “equal”, and “different” mean “substantially the same”, “substantially identical”, “substantially equal”, and “substantially different”, respectively, with allowance for design and manufacturing tolerances and errors.

In addition to what has already been described above, the techniques according to the embodiment and the modified examples may be used in combination as appropriate. Also, while examples are not described, various modifications may be made to the above-described embodiment or modified examples within a range that does not depart from the technical scope thereof.

The problems to be solved by the above-described embodiment and modified examples and effects are not limited to the contents described above. The embodiment, the modified examples, or the like may solve a problem not described above or produce an effect not described above, or may solve only some of the described problems or produce only some of the described effects.

### REFERENCE SIGNS LIST

1 Substrate transport system
7 Vacuum transport chamber (an example of a transport chamber)
9 Processing chamber
11 Stator
13 Mover
13A Mover
13B Mover
13C Mover
13D Mover
13E Mover
13F Mover
13G Mover
14 Controller
15 Opening/closing door
17 Coil unit
19 First magnet unit (an example of a first magnet)
20 Second magnet unit (an example of a second magnet)
21 Substrate support
21A Substrate support
21B Substrate support
21C Substrate support
23 First mover (an example of a first mover)
25 Second mover (an example of a second mover)
27 Bearing (an example of a guide member)
28 Substrate transport device
29 Sensor
31 First target (an example of a first target)
33 Second target (an example of a second target)
35 First mover (an example of a first mover)
37 Second mover (an example of a second mover)
39 Bearing (an example of a guide member)
41A First magnet unit (an example of a first magnet)
41B First magnet unit (an example of a first magnet)
43A Second magnet unit (an example of a second magnet)
43B Second magnet unit (an example of a second magnet)
45 First frame (an example of a first frame)
47 Second frame (an example of a second frame)
48 Arm
49 First arm (an example of a link member)
51 Second arm (an example of a link member)
53 Third arm (an example of a link member)
55 First pulley (an example of a transmission member)
57 Second pulley (an example of a transmission member)
59 Third pulley (an example of a transmission member)
61 Fourth pulley (an example of a transmission member)
67 First mover (an example of a first mover)
69 Second mover (an example of a second mover, an example of the other mover)
71 Linear motion guide (an example of a guide member)
73 Second magnet unit (an example of a second magnet)
75 First mover (an example of a first mover)
77 Second mover (an example of a second mover)
79 Linear motion guide (an example of a guide member)
81A First magnet unit (an example of a first magnet)
81B First magnet unit (an example of a first magnet)
83 Second magnet unit (an example of a second magnet)
85 First mover (an example of a first mover)
87 Second mover (an example of a second mover)
89 Linear motion guide
93 Linear motion guide
97 Elastic body
101 First mover (an example of a first mover)
103 Second mover (an example of a second mover)
105 Linear motion guide (an example of a guide member)
107A First magnet unit (an example of a first magnet)
107B First magnet unit (an example of a first magnet)
109A Second magnet unit (an example of a second magnet)
109B Second magnet unit (an example of a second magnet)
113 First mover (an example of a first mover or one mover)
115 First mover (an example of a first mover or one mover)
117 Second mover (an example of a second mover or the other mover)
AX Rotation axis
AX1 Rotation axis
AX2 Rotation axis
W substrate

1. A substrate transport device comprising:
a stator including a plurality of coils;
a first mover including a first magnet and configured to float and move above the stator;
a second mover including a second magnet and configured to float and move above the stator;
a guide member configured to guide the first mover and the second mover to be operable relative to each other; and
a substrate support connected to at least one of the first mover or the second mover and configured to support a substrate.

2. The substrate transport device according to claim 1, wherein
the first mover includes a first frame in which the first magnet is disposed on the plurality of coils side;
the second mover includes a second frame in which the second magnet is disposed on the plurality of coils side; and
the guide member couples the first frame and the second frame.

3. The substrate transport device according to claim 1, wherein
the first mover and the second mover move above the stator in a state of remaining stationary relative to each other.

4. The substrate transport device according to claim 1, wherein
the guide member regulates operating directions of the first mover and the second mover relative to each other; and
at least one of the first mover or the second mover moves in a direction regulated by the guide member.

5. The substrate transport device according to claim 4, wherein
the first mover is disposed to surround a periphery of the second mover.

6. The substrate transport device according to claim 4, wherein
the guide member regulates the operating directions to a rotating direction about a rotation axis; and
at least one of the first mover or the second mover rotates about the rotation axis.

7. The substrate transport device according to claim 6, wherein
the substrate support is configured to adjust a position with respect to the first mover or the second mover, based on at least one of a rotating direction of each of the first mover and the second mover or a rotation speed of each of the first mover and the second mover.

8. The substrate transport device according to claim 4, wherein
the guide member regulates the operating directions to a linear direction; and
the first mover or the second mover moves in the linear direction.

9. The substrate transport device according to claim 1, wherein
in the stator, a current of a coil in a first region facing the first mover among the plurality of coils and a current of a coil in a second region facing the second mover among the plurality of coils are controlled independently of each other.

10. The substrate transport device according to claim 1, wherein
one mover of the first mover and the second mover includes two or more magnets having orientations different from each other; and
the other mover includes one or more magnets.

11. The substrate transport device according to claim 10, wherein
the two or more magnets having orientations different from each other are disposed on a diagonal line of the one mover.

12. The substrate transport device according to claim 10, wherein
the two or more magnets having orientations different from each other are disposed point-symmetrically about a rotation axis of the one mover.

13. The substrate transport device according to claim 1, wherein
the substrate support includes an arm including at least one of a plurality of link members or a plurality of transmission members and configured to be extendable/contractible, based on operations of the first mover and the second mover relative to each other.

14. The substrate transport device according to claim 1, wherein
the stator includes a plurality of sensors configured to detect positions of the first mover and the second mover;
the first mover includes a first target to be detected by the plurality of sensors; and
the second mover includes a second target to be detected by the plurality of sensors.

15. A substrate transport device comprising:
a stator including a plurality of coils;
a first mover including a first magnet and configured to float and move above the stator;
a second mover including a second magnet and configured to float and move above the stator;
an elastic body configured to couple the first mover and the second mover to be operable relative to each other; and
a substrate support connected to at least one of the first mover or the second mover and configured to support a substrate.

16. A substrate transport system comprising:
a transport chamber including a stator and where a substrate is transported, the stator including a plurality of coils;
a processing chamber disposed at a periphery of the transport chamber and where a predetermined process is executed on the substrate;
an opening/closing door configured to open/close an opening of the processing chamber;
a first mover including a first magnet and configured to float and move above the stator in the transport chamber;
a second mover including a second magnet and configured to float and move above the stator in the transport chamber;
a guide member configured to guide the first mover and the second mover to be operable relative to each other; and
a substrate support connected to at least one of the first mover or the second mover and configured to support the substrate.

17. The substrate transport system according to claim 16, wherein
each of the plurality of coils is configured as a coil unit;
each of the first magnet and the second magnet is configured as a magnet unit facing the coil unit;
the stator, the first mover, and the second mover are configured so that the coil unit and the magnet unit face each other at three or more locations when the first mover or the second mover straddles the opened opening/closing door.

18. A substrate transport method for transporting a substrate, the method comprising:
moving, in a transport chamber including a stator and where the substrate is transported, the stator including a plurality of coils, a first mover and a second mover above the stator in a state of remaining stationary relative to each other, the first mover including a first magnet and configured to float and move above the stator in the transport chamber, the second mover including a second magnet and configured to float and move above the stator in the transport chamber;
operating the first mover and the second mover relative to each other at a position facing a processing chamber disposed at a periphery of the transport chamber and where a predetermined process is executed on the substrate; and
causing a substrate support to enter the processing chamber by opening an opening/closing door configured to open/close an opening of the processing chamber and by causing the first mover or the second mover to straddle the opened opening/closing door, the substrate support connected to at least one of the first mover or the second mover and configured to support the substrate.
